(19) United States
(12) Patent Application Publication
(10) Pub. No.: US 2026/0238735 A1
(43) Pub. Date: Aug. 13, 2026

(54) TELEPROMPTER DEVICE WITH MAGNETS

(71) Applicant: Corsair Memory, Inc., Milpitas, CA (US)

(72) Inventors: Jeffrey Alan Stegner, Milpitas, CA (US); Jörg Gohlke, Milpitas, CA (US)

(21) Appl. No.: 19/639,797

(22) Filed: Apr. 6, 2026

Related U.S. Application Data
(63) Continuation-in-part of application No. 29/902,631, filed on Sep. 14, 2023.
(60) Provisional application No. 63/890,659, filed on Sep. 30, 2025.

(51) Int. Cl. H04N 5/222; H05K 5/02

(52) U.S. Cl. CPC H04N 5/2222; H05K 5/0217

(57) ABSTRACT

A teleprompter device includes a main unit, animaging unit, and a display unit. The main unit includes a base, a housing, and a beam splitter, the base having a supporting surface, a bottom surface, a plurality of side surfaces, and a magnetic component. The imaging unit includes a support frame and animaging module. The display unit includes a display module and a magnetic attachment body. The supporting surface is a planar structure, and the plurality of side surfaces extend from edges of the supporting surface toward the bottom surface, such that the base does not interfere with a display module placed thereon. The magnetic attachment body and the magnetic component magnetically attract each other to fix the display module on the base.

### CROSS-REFERENCE TO RELATED APPLICATIONS

The present application is a continuation-in-part of U.S. Design Patent Application No. 29/902,631, filed on September 14, 2023, and claims the benefit of U.S. Provisional Application No. 63/890,659, filed on September 30, 2025. The entire contents of U.S. Design Patent Application No. 29/902,631 and U.S. Provisional Application No. 63/890,659 are hereby incorporated by reference herein in their entirety.

### TECHNICAL FIELD

The present invention relates to a teleprompter device, more particularly to a teleprompter that utilizes magnetic coupling technology to assemble with a display.

### BACKGROUND

A teleprompter is an auxiliary device commonly used in news broadcasting, public speaking, and program recording to assist a speaker in naturally reading a script while facing the camera. The operating principle is to project or display textual content onto a specially designed glass panel, enabling the speaker to clearly view the text while the camera and audience remain unaware of it, thereby achieving a professional and fluent delivery.

In the design of teleprompters, the manner in which the display is mounted is a critical factor affecting the user experience. A common approach is to secure a mobile device, such as a tablet computer or smartphone, using a clamping mechanism, or to integrate a display directly into the teleprompter housing and secure it by means such as screws, plastic fasteners, or adhesives. However, each of these approaches has inherent limitations.

Although the use of clamps provides a certain degree of flexibility, this is typically only extended to mobile devices such as tablets or smartphones. Larger displays, or displays with more video inputs are typically incompatible with clamping due to their increased size.

In addition, clamp operation can be insecure depending on the device the user attempts to attach, or due to user error. Such improper use can lead to damage to the clamp, or to the mobile device itself.

On the other hand, when screws or adhesives are employed for securing the display, although stability is generally improved, this is generally a permanent application. Thus, such devices that employ screws or adhesives do not have the flexibility to swap out displays easily. Furthermore, the design of the teleprompter becomes a forced design to accommodate the fixedly installed display. Thus, attempts to swap out the display, by removing the screws and/or adhesives, could lead to misalignment of the display to the camera lens position. Misalignment of the display causes the subtitles to be shifted from the center of the camera lens, forcing the speaker to look above or below the camera line which breaks the illusion of eye contact in the recorded image.

From the foregoing description, it can be seen that the current use of teleprompters is subject to the following challenges:

1. Limitation of non-replaceable displays:

In earlier designs where clamps were used to secure the display, the clamps generally supported only specific sizes or models. As a result, once installed, other devices could not be substituted, easily. When the display fails or requires upgrading, the user may be forced to purchase an entirely new teleprompter system or search for compatible accessories, thereby reducing system flexibility and maintenance efficiency.

2. Cumbersome and damage-prone clamps:

The assembly and disassembly procedures of conventional clamps are relatively complicated, making it difficult to quickly install or replace the display. Improper handling can easily result in damage to the clamp or accidental dropping of the display, compromising both operational safety and device lifespan, while also imposing additional burden and risk on on-site personnel.

3. Misalignment of the display affecting line of sight:

In the absence of a precise positioning mechanism, the display in the teleprompter can be off center, causing the speaker to lose the illusion of eye contact with the camera when trying to read the text, which defeats the purpose of a teleprompter.

Accordingly, it is desirable that the design of teleprompters evolve toward modularity and precise positioning, so as to improve the convenience of replacing displays and the accuracy of line-of-sight alignment, thereby meeting diverse usage demands and enhancing overall performance.

### BRIEF DESCRIPTION OF THE DRAWINGS

Referring to the drawings, wherein like numerals refer to like parts throughout the several views and this specification, aspects of presently disclosed principles are illustrated by way of example, and not by way of limitation.

FIG. 1 is a perspective view of a teleprompter device in accordance with a first embodiment of the present invention;

FIG. 2 is a side view of the teleprompter device without shrouds;

FIG. 3 is a perspective view of a display unit separated from a main unit;

FIG. 4 is a side view of the main unit of the first embodiment;

FIG. 5 is a perspective view of the teleprompter device as in FIG. 2;

FIG. 6 is a front view of a first positioning structure;

FIG. 7 is a top view of the first positioning structure as in FIG. 6;

FIG. 8 is a side view of the first positioning structure as in FIG. 6;

FIG. 9 is a front view of a second positioning structure;

FIG. 10 is a top view of the second positioning structure as in FIG. 9;

FIG. 11 is a side view of a main body unit and a display unit of a teleprompter device in accordance with a second embodiment of the present invention; and

FIG. 12 is a side view of a main body unit of a teleprompter device in accordance with a third embodiment of the present invention.

### DESCRIPTION OF EMBODIMENTS

The following describes various principles related to magnetically attachable teleprompters. For example, some disclosed principles pertain to teleprompter systems compatible with a variety of different imaging unit types, sizes, orientations, and features. Further, some disclosed principles pertain to adjustable imaging unit mounts that extend the compatibility of teleprompters across a range of focal lengths, as well as to different users who may gaze at different locations on the teleprompter screen. That said, descriptions herein of specific embodiments are particular examples chosen for convenience to illustrate the disclosed principles. One or more of the disclosed principles can be incorporated into various other embodiments to achieve any of a variety of corresponding system characteristics, as will be apparent from a review of this disclosure.

Accordingly, systems having attributes that differ from those specific features discussed herein can still embody one or more presently disclosed principles, and can be used in applications not described in detail herein. Therefore, such alternative embodiments are also within the scope of this disclosure.

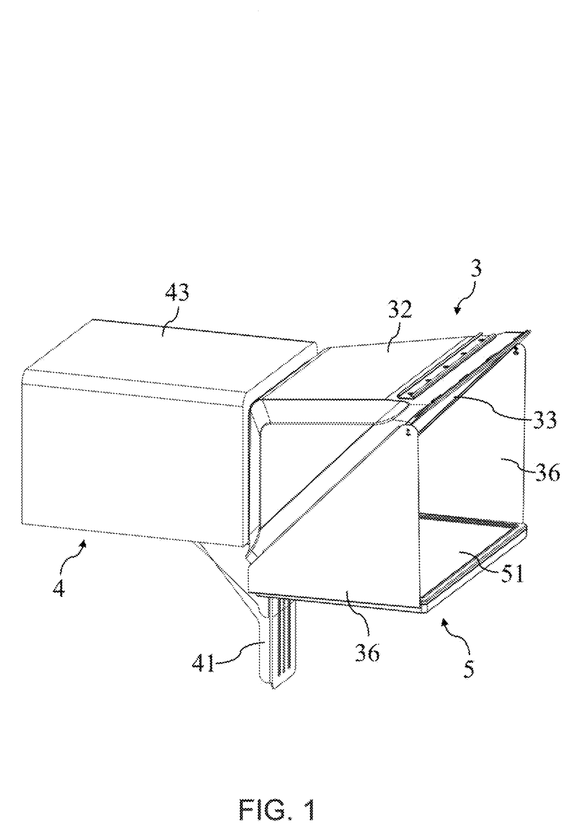

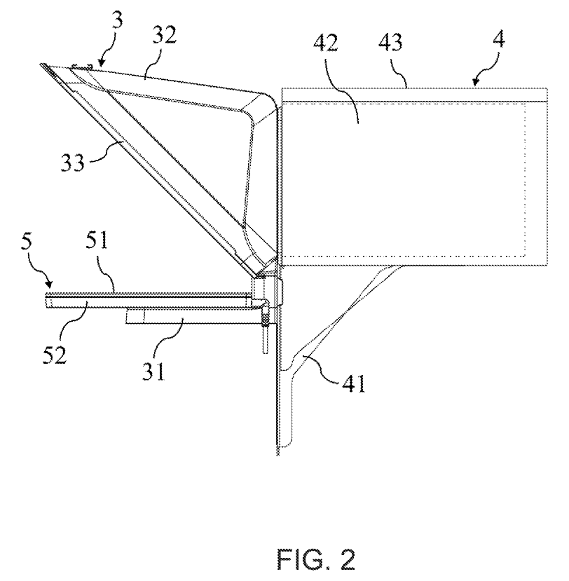

Referring to FIGS. 1, 2, and 3, a teleprompter device in accordance with a first embodiment of the present invention is illustrated. The teleprompter device comprises a main unit 3, an imaging unit 4, and a display unit 5.

The main unit 3 includes a base 31, a housing 32 connected to the base 31, a beam splitter 33 disposed on the housing 32, a plurality of positioning structures provided on the base 31 and connected to a supporting surface 311, and two shrouds 36 disposed on the housing 32 and connected to the display unit 5. The plurality of positioning structures respectively includes a first positioning structure 34 and a second positioning structure 35. In some embodiments, the number of the positioning structures may be one, or three or more. However, according to certain embodiments, there may be no positioning structures. While positioning structures are helpful in some instances, they may not be needed in other instances, depending on the structure and design of the display unit 5.

The imaging unit 4 includes a support frame 41 connected to the base 31, an imaging module 42 disposed on the support frame 41, and an outer cover 43 connected to the housing 32. In some embodiments, the imaging unit 4 may also be implemented without the outer cover 43.

The display unit 5 includes a display module 51, a magnetic attachment body 52 connected to the display module 51, and a plurality of coupling structures disposed on the display module 51. As a non-limiting example, the plurality of coupling structures respectively includes a first coupling structure 53 and a second coupling structure 54. In some embodiments, the number of the coupling structures may be one, or three or more. However, according to certain embodiments, there may be no coupling structures.

The coupling structures are detachably coupled with the positioning structures for securing the placement of the display module 51 on the base 31. For example, the first coupling structure 53 is coupled with the first positioning structure 34, and the second coupling structure 54 is coupled with the second positioning structure 35.

The support frame 41 is fixed to the base 31, and the imaging module 42 is fixed to the support frame 41. The imaging module 42 is a conventional camera, oriented toward the beam splitter 33. The display module 51 is a conventional display screen disposed on the base 31, with its image output directed toward the beam splitter 33. The beam splitter 33 is disposed between the imaging module 42 and the display module 51 at an angle of approximately 45 degrees relative to the imaging direction and the display direction, such that the image output from the display module 51 is reflected while external images are transmitted through to the imaging module 42 for recording, thereby allowing a user to naturally read a script while facing the camera. In some embodiments, the selection of the imaging module 42 and the display module 51 may be determined according to actual circumstances. As a non-limiting example, the display module 51 may alternatively be a conventional television, tablet computer, smartphone, or monitor.

The housing 32 cooperates with the beam splitter 33 to define a dark chamber, thereby enabling the beam splitter 33 to reflect the output image of the display module 51. The two shrouds 36 are respectively disposed at two sides of the beam splitter 33 and are connected to the display module 51, so as to block external light from interfering with the output image, thereby allowing a user to view the output image of the display module 51 more clearly.

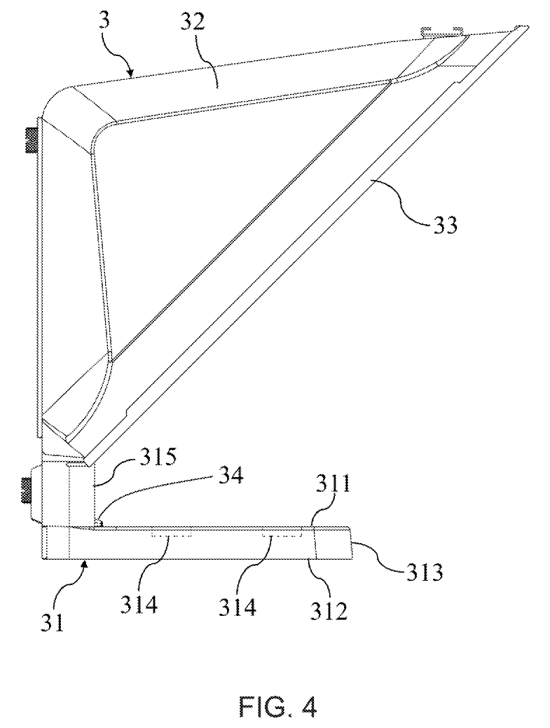

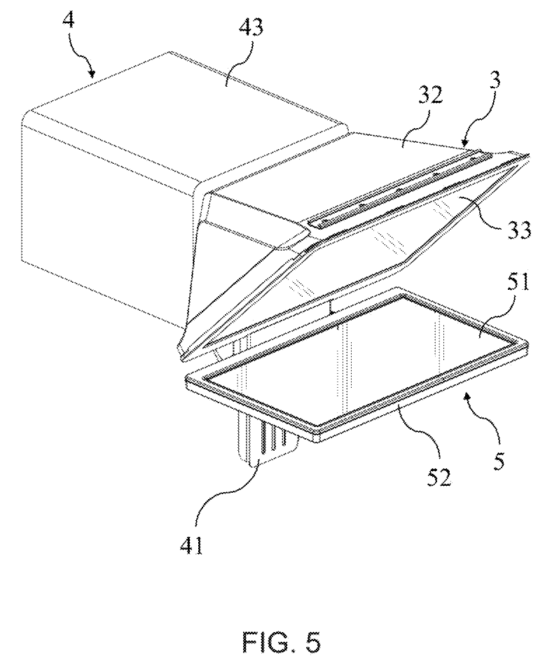

Referring also to FIGS. 4 and 5, the base 31 has a supporting surface 311, a bottom surface 312 spaced apart from the supporting surface 311, a plurality of side surfaces 313 respectively connecting the supporting surface 311 and the bottom surface 312, a magnetic component 314 connected to the supporting surface 311, and a side retaining wall 315 connected to the supporting surface 311.

In some embodiments, the magnetic attachment body 52 is an outer casing of the display module 51, and the supporting surface 311 is a planar structure. The plurality of side surfaces 313 extends from edges of the supporting surface 311 toward the bottom surface 312. The supporting surface 311, the plurality of side surfaces 313, and the bottom surface 312 cooperate to form a flat plate structure. When the display module 51 is placed on the base 31 by means of the magnetic attachment body 52, the base 31 does not interfere with the placed display module 51. Even if the surface area of the magnetic attachment body 52 is greater than that of the supporting surface 311, the portion exceeding the supporting surface 311 merely protrudes beyond the side edge of the base 31 and remains in a suspended state. Accordingly, display modules 51 of different sizes may be placed on the base 31. For example, a 15.6-inch display module 51 on the base 31 may be replaced with a 17-inch display module 51, or a conventional monitor may be replaced with an iPad or iPhone or other display device, simply by removing and replacing the display module 51 on the base 31.

The display module 51 is a rectangular screen. The side retaining wall 315 extends upwardly from an edge of the supporting surface 311. The side retaining wall 315 is configured to abut against one side of the display module 51, thereby providing basic positioning of the display module 51. The housing 32 is mounted on the side retaining wall 315.

The magnetic attachment body 52 and the magnetic component 314 are magnetically attracted to each other so as to secure the display module 51 on the base 31. In some embodiments, the magnetic component 314 comprises a plurality of magnets disposed on the supporting surface 311. As a non-limiting example, four magnets are arranged in a predetermined pattern. In some embodiments, the number of the magnets may be one or any other suitable number. The magnetic component 314 is exposed and thereby provides magnetic attraction to the magnetic attachment body 52. The magnetic attachment body 52 is formed of a material that can be attracted by magnets. For example, the magnetic attachment body 52 may itself be a magnet, or may alternatively be formed of materials such as iron (Fe), nickel (Ni), cobalt (Co), magnetite (Fe₃O₄), neodymium-iron-boron (NdFeB), or aluminum-nickel-cobalt (AlNiCo), among others.

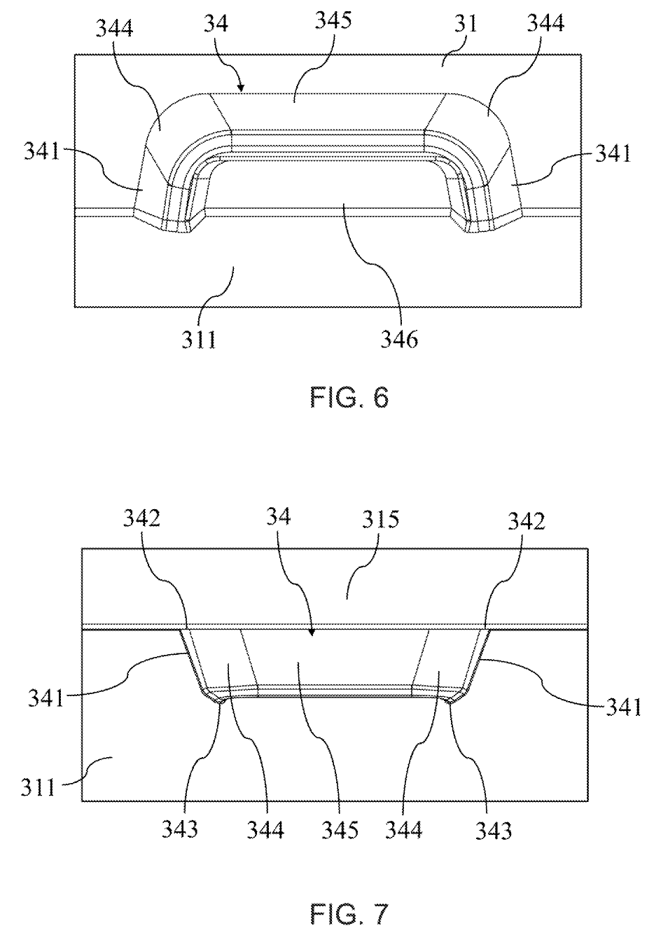

Referring also to FIGS. 6, 7, and 8, the first positioning structure 34 is a block disposed on the supporting surface 311 and connected to the side retaining wall 315. The first positioning structure 34 includes two block sidewalls 341 connected to and spaced apart on the supporting surface 311, a block inner end 342 disposed on the two block sidewalls 341 and connected to the side retaining wall 315, a block outer end 343 disposed on the two block sidewalls 341 opposite to the block inner end 342, two block arcuate guide walls 344 respectively disposed on the tops of the two block sidewalls 341, and a block top wall 345 disposed between the two block arcuate guide walls 344. In some embodiments, the first positioning structure 34 may alternatively not be connected to the side retaining wall 315 and may be disposed at any position on the supporting surface 311.

In some embodiments, the first positioning structure 34 further includes a side recess 346, which is a groove structure having an opening oriented opposite to the side retaining wall 315. In some embodiments, the side recess 346 may be omitted. In some embodiments, magnets of the magnetic component 314 are disposed within the side recess 346 so as to magnetically attract the magnetic attachment body 52, thereby enhancing the fixation of the display module 51.

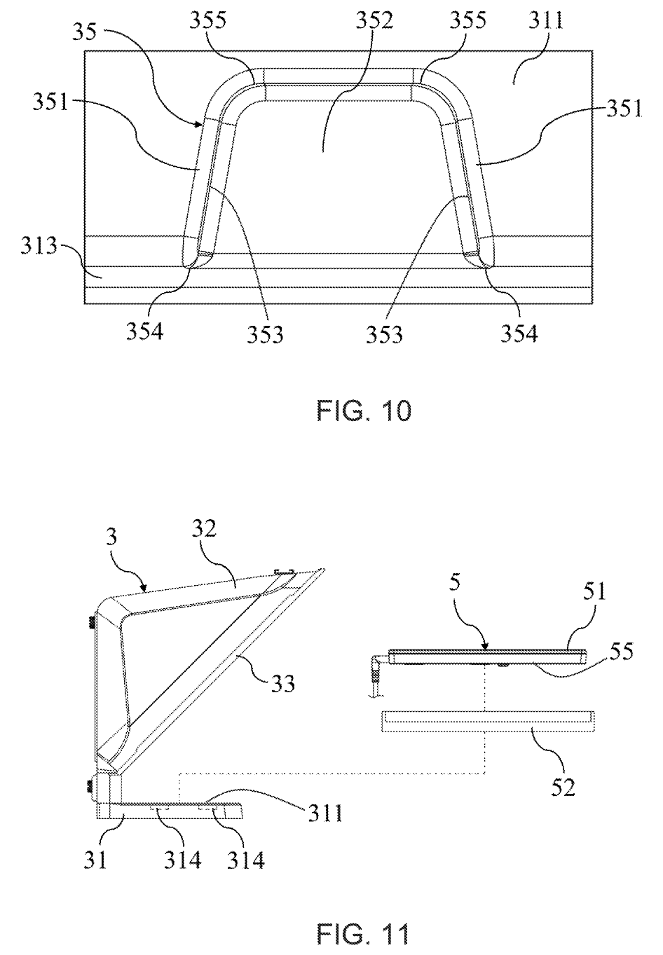

Referring to FIGS. 9 and 10, the second positioning structure 35 is a recess formed in the supporting surface 311 and connected to one of the side surfaces 313. The second positioning structure 35 has two groove arcuate guide walls 351 disposed on the base 31 and connected to the supporting surface 311, a groove bottom wall 352 disposed on the base 31 and located beneath the two groove arcuate guide walls 351, two groove sidewalls 353 disposed on the base 31 and located between the two groove arcuate guide walls 351 and the groove bottom wall 352, a groove outer end 354 disposed on the two groove sidewalls 353 and connected to one of the side surfaces 313, and a groove inner end 355 disposed on the two groove sidewalls 353 opposite to the groove outer end 354. In some embodiments, the second positioning structure 35 may alternatively not be connected to the side retaining wall 315 and may be disposed at any position on the supporting surface 311.

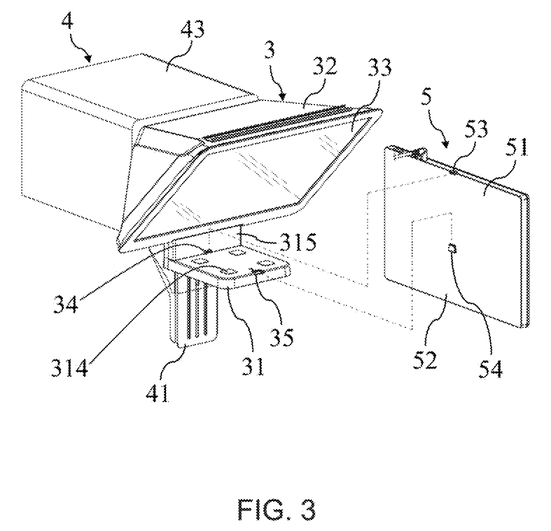

Referring back to FIG. 3, the magnetic attachment body 52 is an outer casing of the display module 51. The first coupling structure 53 is disposed on the magnetic attachment body 52 and engages with the first positioning structure 34 for mutual coupling. The second coupling structure 54 is disposed on the magnetic attachment body 52 and engages with the second positioning structure 35 for mutual coupling. In some embodiments, the magnetic attachment body 52 may also be implemented as an outer casing having magnets or magnetic materials. As a non-limiting example, when the outer casing of the display module 51 is formed of a non-magnetic material, magnetic materials may be disposed on an inner side of the outer casing.

Referring to FIG. 6, the spacing between the two block arcuate guide walls 344 and the spacing between the two block sidewalls 341 gradually increases from the block top wall 345 toward the supporting surface 311 and is curved. The edges of the two block arcuate guide walls 344 are rounded, which facilitates the first coupling structure 53 to be easily inserted into the first positioning structure 34.

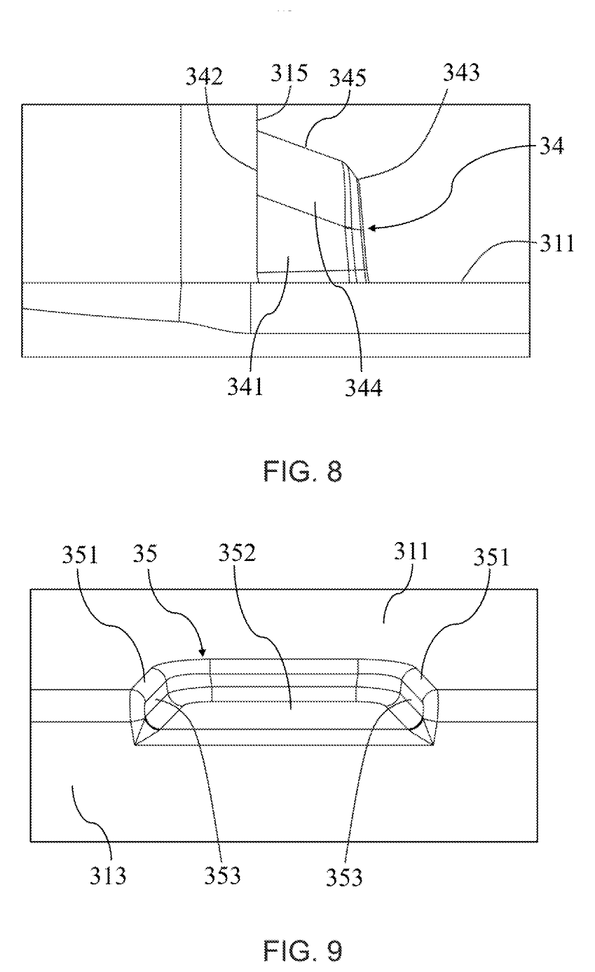

Referring to FIG. 7, the spacing between the two block sidewalls 341 gradually increases from the block outer end 343 toward the block inner end 342. Referring to FIG. 8, the block outer end 343 and the block inner end 342 respectively extend from the two block sidewalls 341 to the block top wall 345. The distance between the block top wall 345 and the supporting surface 311 gradually increases in the direction from the block outer end 343 to the block inner end 342.

As a non-limiting example of the first positioning structure 34, the block outer end 343 has a lower height and a smaller structure compared to the block inner end 342, which allows the first positioning structure 34 to more easily receive the first coupling structure 53, thereby achieving the purpose of coupling and positioning.

In addition, since the first positioning structure 34 is disposed at the junction of the supporting surface 311 and the side retaining wall 315, the display module 51 may first be inserted at an inclined angle so that the first coupling structure 53 engages with the first positioning structure 34. At this stage, the magnetic component 314 and the magnetic attachment body 52 are spaced apart and do not produce a strong magnetic attraction. After positioning, the display module 51 is placed on the supporting surface 311 so that the magnetic attachment body 52 contacts the magnetic component 314, generating magnetic attraction to prevent the display module 51 from falling off the base 31.

Furthermore, when it is necessary to remove or replace the display module 51 on the base 31, the display module 51 may be simply lifted off, thereby quickly achieving the replacement of the device.

Referring to FIG. 9, the spacing between the two groove arcuate guide walls 351 gradually decreases from the supporting surface 311 toward the groove bottom wall 352 and is curved. The edges of the two groove arcuate guide walls 351 are rounded, which facilitates the second coupling structure 54 to be easily inserted into the second positioning structure 35.

Referring to FIG. 10, the spacing between the two groove sidewalls 353 gradually decreases from the groove outer end 354 toward the groove inner end 355. Since the groove outer end 354 is connected to the side surface 313, the second positioning structure 35 forms an open groove with a relatively large opening, thereby allowing the second coupling structure 54 to be more easily pushed into the second positioning structure 35.

An arrow is provided on a side of the second positioning structure 35 disposed on the supporting surface 311 (as shown in FIG. 3) to guide a user to push the display module 51 toward the side retaining wall 315, so that the first coupling structure 53 engages with the first positioning structure 34 and the second coupling structure 54 engages with the second positioning structure 35.

Referring to FIG. 11, a teleprompter device in accordance with a second embodiment of the present invention is illustrated. The second embodiment is generally similar to the first embodiment, and the same elements will not be described in detail herein. The difference lies in that, in the second embodiment, the display unit 5 further includes a casing 55 connected to the display module 51. The display module 51 is disposed within the casing 55, and the casing 55 is fitted onto the magnetic attachment body 52, so that a magnetic connection is established between the magnetic attachment body 52 and the magnetic component 314.

The casing 55 is a conventional casing of a display, and may be formed of materials such as aluminum alloy or plastic, for enclosing the electronic components of the display module 51. The magnetic attachment body 52 serves as an outer protective sleeve for the casing 55, similar to a protective case used for a smartphone.

For example, magnets are provided in the magnetic attachment body 52, so that when the display module 51 is placed on the base 31, the magnetic component 314 and the magnetic attachment body 52 magnetically attract each other. In some embodiments, the magnetic attachment body 52 may alternatively be formed of other magnetic materials, or entirely of a magnetic material.

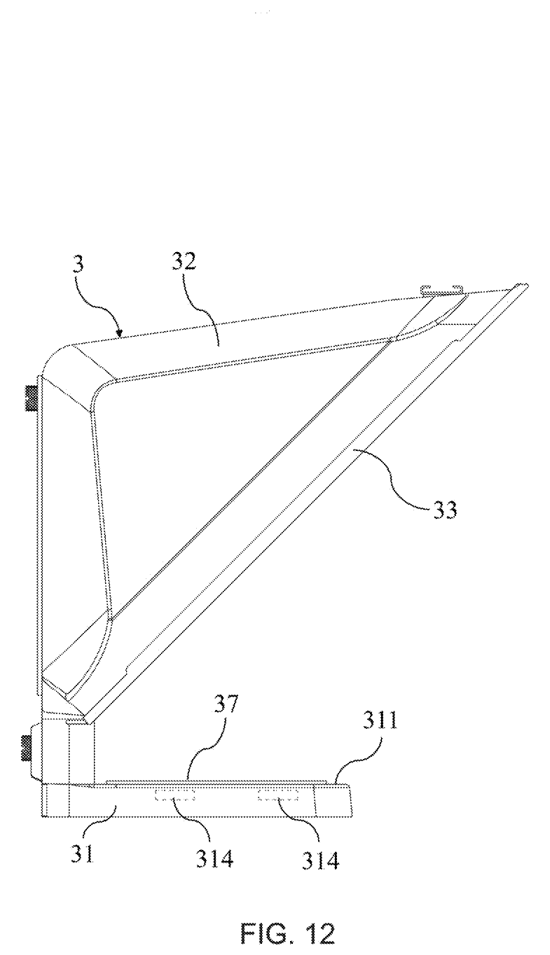

Referring to FIG. 12, a teleprompter device in accordance with a third embodiment of the present invention is illustrated. The third embodiment is generally similar to the first embodiment, and the same elements will not be described in detail herein. The difference lies in that, in the third embodiment, the magnetic component 314 is disposed inside the base 31, and the main unit 3 further includes at least one cushion layer 37 provided on the supporting surface 311.

As a non-limiting example, the base 31 has a plastic outer shell, and the magnetic component 314 comprises two magnets disposed inside the base 31. The magnetic component 314 generates a magnetic force through the outer shell of the base 31 to magnetically hold the display module 51 placed above the base 31. In some embodiments, the magnetic component 314 may alternatively comprise a single magnet, or three or more magnets.

The cushion layer 37 comprises at least one pad attached to the supporting surface 311 of the base 31. In some embodiments, the cushion layer 37 may be formed of high-density foam to prevent damage caused by friction between the display module 51 and the base 31 during movement of the display module 51. For example, the cushion layer 37 comprises a single pad. In some embodiments, the number of cushion layers 37 may be multiple. In some embodiments, the cushion layer 37 may be a coating provided on the surface of the base 31, which is scratch-resistant to protect the surface of the base 31.

From the foregoing description, it can be seen that the teleprompter device, according to the present invention, achieves the following features:

1. Freely replaceable display:

Since the base 31 does not interfere with the placed display module 51, when the surface area of the casing 55 of the display module 51 is larger than that of the supporting surface 311, the portion extending beyond the supporting surface 311 merely protrudes beyond the side edges of the base 31 in a suspended state and does not affect the image projection function. Therefore, the base 31 can accommodate display modules 51 of different sizes.

2. Simple and quick operation:

The magnetic attachment body 52 and the magnetic component 314 magnetically attract each other. The first positioning structure 34 is disposed at the junction of the supporting surface 311 and the side retaining wall 315. Therefore, the display module 51 may first be inserted at an inclined angle so that the first coupling structure 53 engages with the first positioning structure 34. At this stage, the magnetic component 314 and the magnetic attachment body 52 are spaced apart and do not produce a strong magnetic attraction, allowing the position to be adjusted simply and quickly. Subsequently, the display module 51 is placed on the base 31, thereby completing the installation of the display module 51.

3. Rapid positioning aligned with the line of sight:

The side retaining wall 315 abuts one side of the display module 51. In the first positioning structure 34, the block outer end 343 has a lower height and smaller structure compared to the block inner end 342. The second positioning structure 35 forms an open groove with a relatively large opening. When the display module 51 is placed on the base 31, it may be precisely positioned with a gentle push, enabling the user to clearly view the image projected by the display module 51.

In certain other embodiments, there are no positioning structures and no corresponding coupling structures. In such embodiments, the magnetic attachment body 52 and the magnetic component 314 are magnetically attracted to each other so as to secure the display module 51 on the base 31 without positioning structures and corresponding coupling structures. For example, a user may eye-ball the positioning of the display module 51 by holding the display module 51 just above the base 31 before releasing the display module 51 onto the base 31 and letting the magnets in the magnetic attachment body 52 and the magnetic component 314 attract each other. As another example, a user may release the display module onto the base 31 using the magnetic attraction and then slide/rotate the display module 51 into the desired position on the base 31.

In summary, by means of the first positioning structure 34 and the second positioning structure 35, the display module 51 can be quickly secured on the base 31, allowing the user to clearly view the image projected by the display module 51. In combination with the magnetic attraction between the magnetic attachment body 52 and the magnetic component 314, the display module 51 is held in place and prevented from falling off the base 31. The first positioning structure 34 allows the first coupling structure 53 of the display module 51 to be easily engaged with the first positioning structure 34 whether the display module 51 is placed from above, from the side, or at an inclined angle, without requiring complicated operations. Accordingly, the installation of the display module 51 can be accomplished easily, thereby achieving the objectives of the present invention. Alternatively, the magnetic attraction between the magnetic attachment body 52 and the magnetic component 314 work to secure the display module 51 onto the base 31, without the aid of positioning structures and corresponding coupling structure.

According to certain embodiments, the teleprompter device comprises a main unit 3, including a base 31, a housing 32 connected to the base 31, and a beam splitter 33 disposed on the housing 32, wherein the base 31 has a supporting surface 311, a bottom surface 312 spaced apart from the supporting surface 311, a plurality of side surfaces 313 respectively connecting the supporting surface 311 and the bottom surface 312, and a magnetic component 314 connected to the supporting surface 311. The embodiment further comprises an imaging unit 4, including a supporting frame 41 connected to the base 31, and an imaging module 42 disposed on the supporting frame 41 and a display unit 5, including a display module 51 and a magnetic attachment body 52 connected to the display module 51, wherein the supporting surface 311 is a planar structure, the plurality of side surfaces 313 extend from edges of the supporting surface 311 toward the direction of the bottom surface 312, and the magnetic attachment body 52 and the magnetic component magnetically attract each other to fix the display module 51 disposed on the base 31.

According to certain embodiments, the magnetic attachment body 52 is an outer casing of the display module 51.

According to certain embodiments, the display unit 5 further includes a casing 55 connected to the display module 51, the display module 51 is disposed in the casing 55, and the casing 55 is fitted onto the magnetic attachment body 52, wherein the magnetic attachment body 52 is magnetically connected to the magnetic component 314.

According to certain embodiments, the main unit 3 further includes at least one positioning structure 34, 35 disposed on the base 31 and connected to the supporting surface 311, and the display unit 5 further includes at least one coupling structure 53, 53 disposed on the display module 51, wherein the coupling structure is detachably engaged with the positioning structure to fix the display module 51 on the base 31.

According to certain embodiments, the base 31 further has a side retaining wall 315 connected to the supporting surface 311, the side retaining wall 315 extends upward from a side edge of the supporting surface 311, the positioning structure 34, 35 is a block disposed on the supporting surface 311 and connected to the side retaining wall 315, the positioning structure has two block side walls 341 connected to the supporting surface 311, a block inner end 342 disposed on the two block side walls 341 and connected to the side retaining wall 315, and a block outer end 343 disposed on the two block side walls and opposite to the block inner end 342, wherein the spacing between the two block side walls gradually increases from the block outer end 343 to the block inner end 342.

According to certain embodiments, the positioning structure 34, 35 further has two block arcuate guide walls 344 respectively disposed on the top of the two block side walls 341, and a block top wall 345 disposed between the two block arcuate guide walls, wherein the spacing between the two block arcuate guide walls and the spacing between the two block side walls 341 gradually increases from the block top wall 345 toward the direction of the supporting surface 311.

According to certain embodiments, the block outer end 343 and the block inner end 342 respectively extend from the two block side walls 341 to the block top wall, and the distance between the block top wall 345 and the supporting surface 311 gradually increases from the block outer end 343 toward the direction of the block inner end 342.

According to certain embodiments, the positioning structure is a recess in the supporting surface 311, the positioning structure 34, 35 has two groove arcuate guide walls 351 disposed on the base 31 and connected to the supporting surface 311, and a groove bottom wall 352 disposed on the base 31 and located beneath the two groove arcuate guide walls 351, wherein the spacing between the two groove arcuate guide walls 351 gradually decreases from the supporting surface 311 toward the groove bottom wall 352.

According to certain embodiments, the positioning structure 34, 35 further has two groove side walls 353 disposed on the base 31 and located between the two groove arcuate guide walls 351 and the groove bottom wall 352, a groove outer end 354 disposed on the two groove side walls 353 and connected to one of the side surfaces, and a groove inner end 355 disposed on the two groove side walls 353 and opposite to the groove outer end 354, wherein the spacing between the two groove side walls 353 gradually decreases from the groove outer end 354 to the groove inner end 355.

According to certain embodiments, the magnetic component 314 is disposed inside the base 31, and the main unit 3 further includes at least one cushion layer 37 disposed on the supporting surface 311, and two shrouds 36 disposed on the housing 32 and connected to the display module 51, the two shrouds 36 being disposed on opposite sides of the beam splitter 33.

According to certain embodiments, the magnetic attraction between the magnetic attachment body 52 and the magnetic component 314 work to secure the display module 51 onto the base 31, without the aid of positioning structures and corresponding coupling structure.

Those of ordinary skill in the art will appreciate that the exemplary embodiments disclosed herein can be adapted to various configurations and/or uses without departing from the disclosed principles. For example, the principles

described above in connection with any particular example can be combined with the principles described in connection with another example described herein. Thus, all structural and functional equivalents to the features and method acts of the various embodiments described throughout the disclosure that are known or later come to be known to those of ordinary skill in the art are intended to be encompassed by the principles described and the features and acts claimed herein. Accordingly, neither the claims nor this detailed description shall be construed in a limiting sense, and following a review of this disclosure, those of ordinary skill in the art will appreciate the wide variety of teleprompters, and related methods and systems that can be devised using the various concepts described herein.

1. A teleprompter device comprising:
a main unit 3,
wherein the main unit 3 includes a base 31, a housing 32 connected to the base 31, and a beam splitter 33 disposed on the housing 32,
wherein the base 31 has an upper surface 311, a bottom surface 312 vertically spaced apart from the upper surface 311, a plurality of side surfaces 313 respectively connecting the upper surface 311 and the bottom surface 312, and a magnetic component 314 disposed in the upper surface 311; and
an imaging unit 4 operable to receive an imaging module 42, the imaging unit 4 including a supporting frame 41 connected to the base 31.

2. The teleprompter device of claim 1,
wherein the supporting frame 41 is configured to mount the imaging module 42 thereon when the imaging module 42 is received by the imaging unit 4.

3. The teleprompter device of claim 1,
wherein the upper surface 311 is in a planar structure, and the plurality of side surfaces 313 extend from edges of the upper surface 311 toward the bottom surface 312.

4. The teleprompter device of claim 1,
wherein the magnetic component 314 of the base 31 includes a plurality of base magnets.

5. The teleprompter device of claim 1,
wherein the upper surface 311 is configured to mount a display unit 5 thereon,
wherein the magnetic component 314 is configured to attract the display unit 5 and secure a horizontal position of the display unit 5 by a magnetic force when the display unit 5 is mounted on the upper surface 311.

6. The teleprompter device of claim 1,
further comprising a display unit 5 detachably mounted on the upper surface 311,
wherein a horizontal area of the display unit 5 is larger than a horizontal area of the upper surface 311,
wherein the display unit 5 includes a display module 51 and a magnetic attachment body 52,
wherein the magnetic attachment body 52 is configured to be attracted to the magnetic component 314 by a magnetic force when mounted on the upper surface 311, thereby securing a horizontal position of the display unit 5.

7. The teleprompter device of claim 6,
wherein the magnetic attachment body 52 includes a display unit magnet,
wherein, when the display unit 5 is mounted on the upper surface 311, the magnetic component 314 and the display unit magnet are attracted to each other and arranged in vertically corresponding positions by the magnetic force from the magnetic component 314 and a magnetic force from the display unit magnet.

8. The teleprompter device of claim 6,
wherein the magnetic attachment body 52 is an outer casing of the display module 51.

9. The teleprompter device of claim 6,
wherein the display unit 5 further includes a display module casing 55,
wherein the display module 51 is disposed in the display module casing 55, and the display module casing 55 is fitted onto the magnetic attachment body 52,
wherein the magnetic attachment body 52 is magnetically connected to the magnetic component 314.

10. The teleprompter device of claim 6,
wherein the main unit 3 further includes at least one positioning structure 34, 35 disposed on the base 31 and connected to the upper surface 311,
wherein the display unit 5 further includes at least one coupling structure 53, 54, and
wherein the at least one coupling structure 53, 54 is detachably engaged with and received by the at least one positioning structure 34, 35 to fix the display unit 5 on the base 31.

11. The teleprompter device of claim 1,
wherein the main unit 3 further includes at least one positioning structure 34, 35, disposed on the base 31 and connected to the upper surface 311,
wherein the base 31 further includes a side retaining wall 315 connected to the upper surface 311, the side retaining wall 315 extending upward from a rear end edge of the upper surface 311,
wherein the at least one positioning structure 34, 35 includes a block disposed on the upper surface 311 and connected to the side retaining wall 315,
the block including two block side walls 341 connected to the upper surface 311, a block rear end 342 disposed on the two block side walls 341 and connected to the side retaining wall 315, and a block front end 343 disposed on the two block side walls 341 and opposite the block rear end 342,
wherein a spacing between external surfaces of the two block side walls 341 gradually increases from the block front end 343 to the block rear end 342.

12. The teleprompter device of claim 11,
wherein the at least one positioning structure 34, 35 further includes two block arcuate guide walls 344 respectively disposed on tops of the two block side walls 341, and a block top wall 345 disposed between the two block arcuate guide walls 344,
wherein a spacing between the two block arcuate guide walls 344 and a spacing between the two block side walls 341 gradually increases in a direction from the block top wall 345 toward the upper surface 311.

13. The teleprompter device of claim 12,
wherein the block front end 343 and the block rear end 342 respectively extend from the two block side walls 341 to the block top wall 345, and
wherein a distance between an outer surface of the block top wall 345 and the upper surface 311 gradually increases in a direction from the block front end 343 toward the block rear end 342.

14. The teleprompter device of claim 13,
further comprising a display unit 5 detachably mounted on the upper surface 311, the display unit 5 including at least one coupling structure 53, 54,
wherein, when a width direction is defined as a horizontal direction perpendicular to a direction extending from the front end edge of the upper surface 311 toward the rear end edge of the upper surface 311,
the block forms a block groove and is disposed at a center in the width direction and at the rear end edge of the upper surface 311,
the at least one coupling structure 53, 54 includes a first protrusion formed at an edge of the display unit 5, and
the block groove is configured to receive the first protrusion.

15. The teleprompter device of claim 1,
wherein the main unit 3 further includes at least one positioning structure 34, 35, disposed on the base 31 and connected to the upper surface 311,
wherein the at least one positioning structure 34, 35 includes a recess formed on the upper surface 311,
the recess including two groove arcuate guide walls 351 disposed on the base 31 and connected to the upper surface 311, and a groove bottom wall 352 disposed on the base 31 and located beneath the two groove arcuate guide walls 351,
wherein a spacing between the two groove arcuate guide walls 351 gradually decreases in a direction from the upper surface 311 toward the groove bottom wall 352.

16. The teleprompter device of claim 15,
wherein the recess further includes two groove side walls 353 disposed on the base 31 and located between the two groove arcuate guide walls 351 and the groove bottom wall 352, a groove front end 354 disposed on the two groove side walls 353 and connected to one of the side surfaces 313, and a groove rear end 355 disposed on the two groove side walls 353 and opposite the groove front end 354,
wherein a spacing between the two groove side walls 353 gradually decreases in a direction from the groove front end 354 to the groove rear end 355.

17. The teleprompter device of claim 16,
further comprising a display unit 5 detachably mounted on the upper surface 311, the display unit 5 including at least one coupling structure 53, 54,
wherein a width direction is defined as a horizontal direction perpendicular to a direction extending from the front end edge of the upper surface 311 toward the rear end edge of the upper surface 311,
wherein the recess is disposed at a center in the width direction and at the front end edge of the upper surface 311,
wherein the at least one coupling structure 53, 54 includes a second protrusion formed within a bottom surface of the display unit 5,
wherein the recess is configured to receive the second protrusion.

18. The teleprompter device of claim 1,
wherein the magnetic component 314 is disposed inside the base 31, and the main unit 3 further includes at least one cushion layer 37 disposed on the upper surface 311, and two shrouds 36 disposed on the housing 32, the two shrouds 36 being disposed on opposite sides of the beam splitter 33.

19. A teleprompter device comprising:
a main unit 3,
wherein the main unit 3 includes a base 31, a housing 32 connected to the base 31, and a beam splitter 33 disposed on the housing 32,
wherein the base 31 has an upper surface 311, a bottom surface 312 vertically spaced apart from the upper surface 311, and a plurality of side surfaces 313 respectively connecting the upper surface 311 and the bottom surface 312;
an imaging unit 4, operable to receive an imaging module 42, the imaging unit 4 including a supporting frame 41 connected to the base 31; and
a display unit 5 detachably mounted on the upper surface 311, a horizontal area of the display unit 5 being larger than a horizontal area of the upper surface 311,
wherein the main unit 3 includes a block and a recess, the block, forming a block groove, being disposed at a center in a width direction and at a rear end edge of the upper surface 311, and the recess being disposed at a center in the width direction and at a front end edge of the upper surface 311,
wherein the display unit 5 includes a first protrusion formed at an edge of the display unit 5 and a second protrusion formed on a bottom surface of the display unit 5,
wherein the block groove receives the first protrusion and the recess receives the second protrusion.
